(19) United States
(12) Patent Application Publication
(10) Pub. No.: US 2020/0221868 A1
(43) Pub. Date: Jul. 16, 2020

(54) Rail Assembly for Server Cabinet

(71) Applicant: Chi Feng Hsu, New Taipei City (TW)

(72) Inventor: Chi Feng Hsu, New Taipei City (TW)

(21) Appl. No.: 16/245,690

(22) Filed: Jan. 11, 2019

(51) Int. Cl. A47B 88/43; A47B 88/49; A47B 88/477; H05K 7/18; H05K 7/14

(52) U.S. Cl. CPC A47B 88/43; A47B 88/49; A47B 2210/0081; H05K 7/183; H05K 7/1489; A47B 88/477

(57) ABSTRACT

A rail assembly includes a panel, a first rail, a second rail, an installation device, a support device and a locking device. The panel is connected to the locking device and one side of the first rail. The second rail is mounted to the first rail. The installation device includes a first part and a second part respectively connected to the first and second rails. The support device is connected to one side of the second rail and supports the shelves. The locking device is located between the panel and the first rail. The locking device includes a release member and a locking member. The locking device prevents the first rail from separating from the second rail.

### BACKGROUND OF THE INVENTION

### 1. Fields of the Invention

The present invention relates to a rail assembly for a server cabinet, and more particularly, to a rail assembly for balancing weight center when operation.

### 2. Descriptions of Related Art

The conventional rail assembly for server cabinets generally includes a first rail and a second rail, wherein the first rail is slidable relative to the second rail. When the server is moved, the weight center is moved, and the change of the weight center may cause the cabinet to fall in one direction.

Besides, the cabinet and the shelves each have a manufacturing tolerance which can make the gap between the cabinet and the shelves be too small or too big. Therefore, the rail assembly cannot be smoothly operated.

When the server on the first rail is moved in one direction, the first rail may drop off from the second rail if the users do not pay attention and therefore the server can be damaged.

The present invention intends to provide a rail assembly for a server cabinet to eliminate the above mentioned shortcomings.

### SUMMARY OF THE INVENTION

The present invention relates to a rail assembly and comprises a panel, a first rail, a second rail, an installation device, a support device and a locking device. The panel includes a second engaging portion formed thereto, and is connected to the locking device and one side of the first rail. The locking device is located between the panel and the first rail. The locking device includes a first contact portion which is located corresponding to the second engaging portion by a resilient member. The second rail is mounted to the first rail, and the installation device and the support device are connected to the second rail. The installation device is connected to one end of the second rail and includes a connection member which includes a first part and a second part. The support device is connected to one side of the second rail and includes a support member. The support member includes a first engaging portion, a second engaging portion, a support portion and a bore. The locking device includes a release member and a locking member. The release member includes multiple elongate holes, an extension, the first contact portion and the resilient member. The locking member includes a first engaging part, a second engaging part, a slot, a torsion spring and a pivot member.

Preferably, the first part includes a first hole, and the second part includes a second hole. The first and second holes each are an oval hole and are respectively and transversely defined in the first and second parts. A pin movably extends through the oval hole.

Preferably, a bolt extends through the bore of the support member and contacts against the second rail. The support portion is located corresponding to a shelf.

Preferably, the second rail includes a stop which is located corresponding to the locking member of the locking device.

Preferably, the release member of the locking device is movable in one direction to contact and pivot the locking member, and the first rail is pushed to separate from the second rail.

The primary object of the present invention is to provide a rail assembly that can easily adjust the manufacturing tolerances of the cabinet and the shelves.

Another object of the present invention is to provide a rail assembly that prevents the first rails from separating from the second rail.

Yet another object of the present invention is to provide a rail assembly that balances the weight center when pulling or pushing the servers.

The present invention will become more apparent from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the rail assembly of the present invention;

FIG. 2 is a perspective view to show the rail assembly of the present invention;

FIG. 3 shows the gap between the rack post and the cabinet;

FIG. 4 shows the installation device of the rail assembly of the present invention;

FIG. 5 shows the first part of the installation device of the rail assembly of the present invention;

FIG. 6 shows the second part of the installation device of the rail assembly of the present invention;

FIG. 7 is a cross sectional view to show installation of the support device of the rail assembly of the present invention;

FIG. 8 shows the support device of the rail assembly of the present invention;

FIG. 9 shows the locking device of the rail assembly of the present invention, and

FIGS. 10 to 12 show the operation of the locking device of the rail assembly of the present invention.

### DETAILED DESCRIPTION OF THE PREFERRED EMBODIMENT

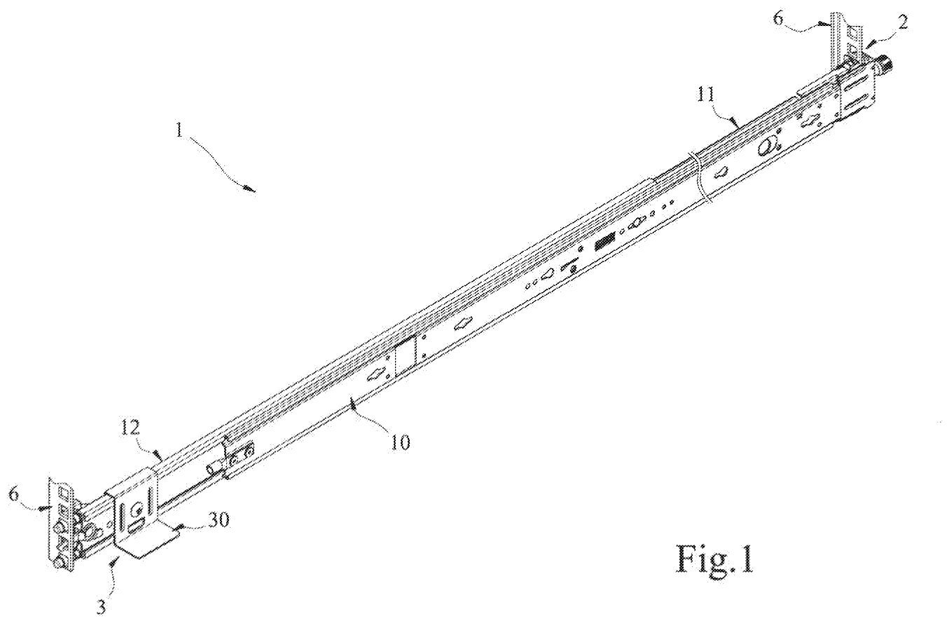

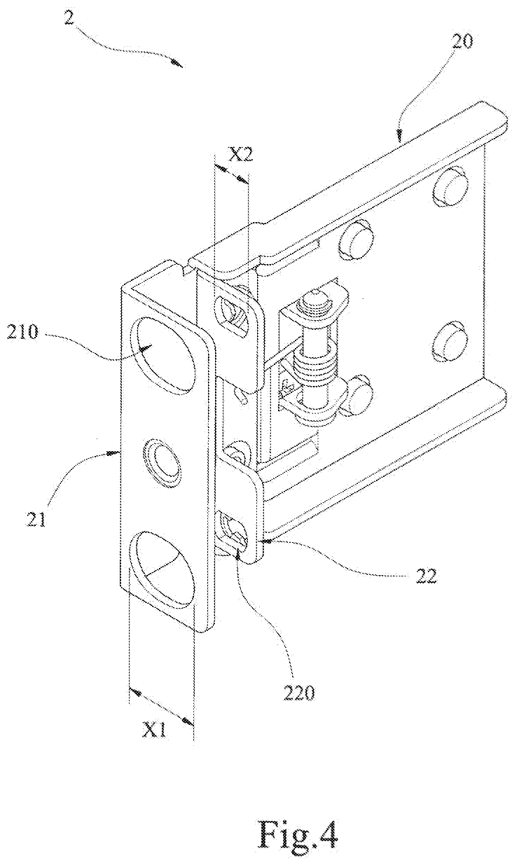

Referring to FIGS. 1, 2, 4, 7 and 8, the rail assembly 1 of the present invention comprises a panel 10, a first rail 11, a second rail 12, an installation device 2, a support device 3 and a locking device 4.

The panel 10 includes a second engaging portion 100 formed thereto, and the panel 10 is connected to the locking device 4 and one side of the first rail 11, wherein the locking device 4 is located between the panel 10 and the first rail 11.

The second rail 12 is mounted to the first rail 11 which is slidable relative to the second rail 12. By the locking device 4, the first rail 11 is slidable relative to the second rail 12, and the first rail 11 is prevented from separating from the second rail 12.

The second rail 12 includes the installation device 2 and the support device 3 connected thereto, wherein the support device 3 balances the weight center of the shelves and the servers, and the installation device 2 adjusts the manufacturing tolerances of the shelves and the racks.

The installation device 2 is connected to each of two ends of the second rail 12 and includes a connection member 20 which includes a first part 21 and a second part 22. The first part 21 includes two first holes 210, and the second part 22 includes two second holes 220. The first and second holes 210, 220 each are an oval hole and are respectively and transversely defined in the first and second parts 21, 22, and a pin 23 movably extends through the oval holes so as to adjust in transverse direction relative to the holes of the rack posts 6.

The support device 3 is connected to one side of the second rail 12 and includes a support member 30 which includes a first snapping portion 301, a second snapping portion 302, a support portion 303 and a bore 304. The first snapping portion 301 is located corresponding to the engaging end 120 of the second rail 12. The second snapping portion 302 is located corresponding to the ridge 121 of the second rail 12. The support portion 303 is located corresponding to the shelves 5. The bore 304 is located corresponding to the side of the second rail 12 that the bolt 31 contacts against.

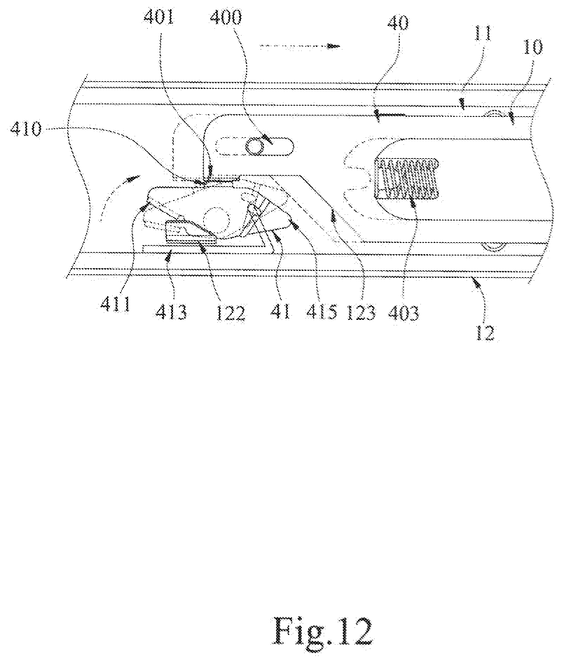

The locking device 4 includes a release member 40 and a locking member 41. The release member 40 includes multiple elongate holes 400, an extension 401, a first contact portion 402, a resilient member 403, and a through hole 404. The elongate holes 400 are located on two ends of the release member 40 and bolts extend through the elongate holes 400 so that the release member 40 is movable transversely. The extension 401 is formed on one end of the release member 40 and perpendicular to the release member 40. The extension 401 is located corresponding to the first engaging part 4410 of the locking member 41. The first contact portion 402 includes a protrusion which is located corresponding to the resilient member 403. The resilient member 403 is biased between the first contact portion 402 and the second engaging portion 100. The resilient member 403 provides a force which always biases the release member 40. The through hole 404 allows the release member 40 to move transversely and to release from locked status. The locking member 41 includes a first engaging part 410, a second engaging part 411, a slot 412, a torsion spring 413 and a pivot member 414. The first engaging part 410 extends perpendicularly from the top of the locking member 41 and located corresponding to the extension 401 of the release member 40. The second engaging part 411 extends perpendicularly from one end of the locking member 41 and located corresponding to the stop 122 of the second rail 12 as shown in FIG. 12. The slot 412 is located at one end of the torsion spring 413. The pivot member 414 extends through the locking member 41 and connected to the panel 10.

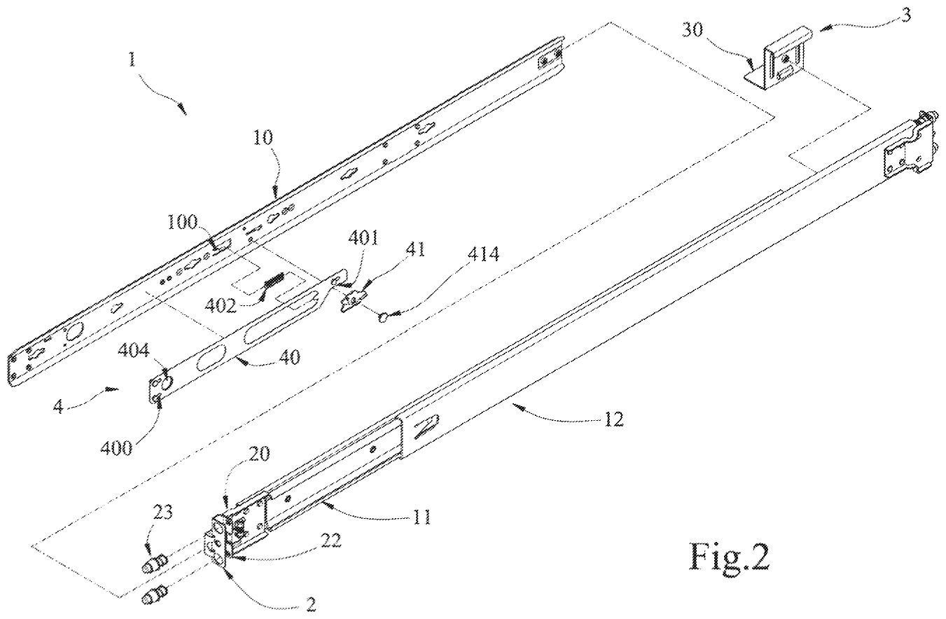

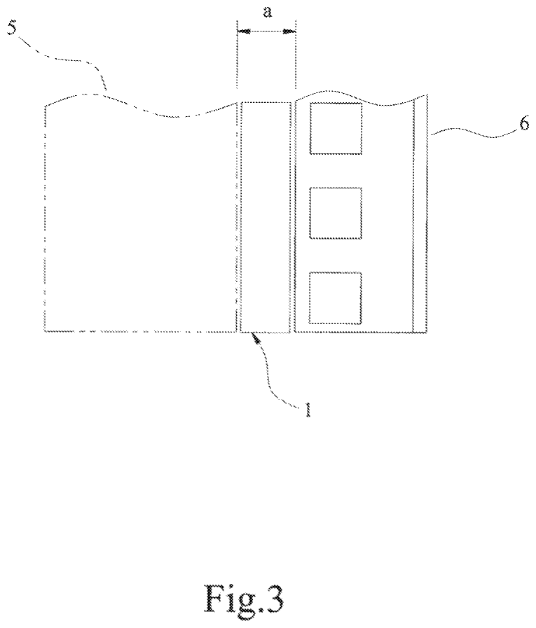

As shown in FIGS. 2, 3, 4, 5 and 6, the gap “a” is formed between the shelf 5 and the rack 6, and the gap “a” may have different values due to manufacturing tolerances. The installation device 2 is used to connect the shelf 5 and the rack 6. The installation device 2 is connected to one end of the second rail 12 and includes a connection member 20 which includes a first part 21 and a second part 22. The first part 21 includes two first holes 210 and each of the first holes 210 is an elongated and oval hole in which a first adjustment space X1 is formed. The pin 23 is located corresponding to the first hole 210.

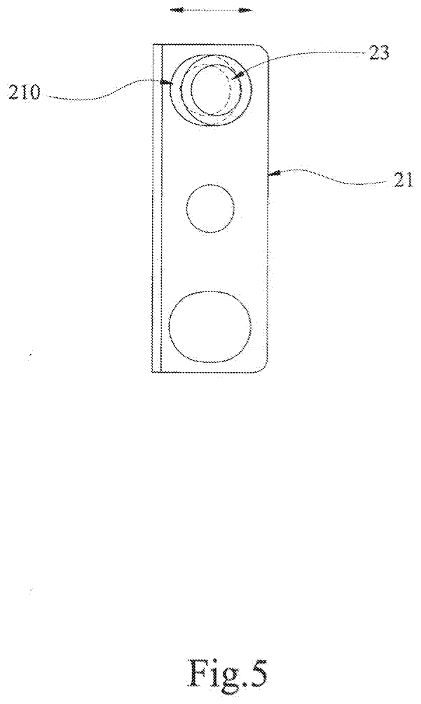

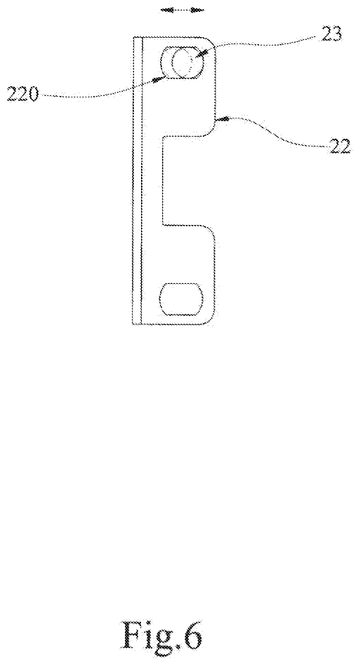

The second part 22 includes two second holes 220 and each of the second holes 220 is an elongated and oval hole in which a second adjustment space X2 is formed. The pin 23 is located corresponding to the second hole 220. The two respective centers of the first and second holes 210, 220 are located corresponding to each other so that the pins 23 can be co-axially adjusted. As shown in FIGS. 5 and 6, the front portion of the pin 23 is located in the first hole 210 and can be moved transversely. In the meanwhile, the rear portion of the pin 23 is transversely adjusted as well. After the final position is reached, a C-clip is used to secure so that the gap “a” can be compensated by the installation device 2.

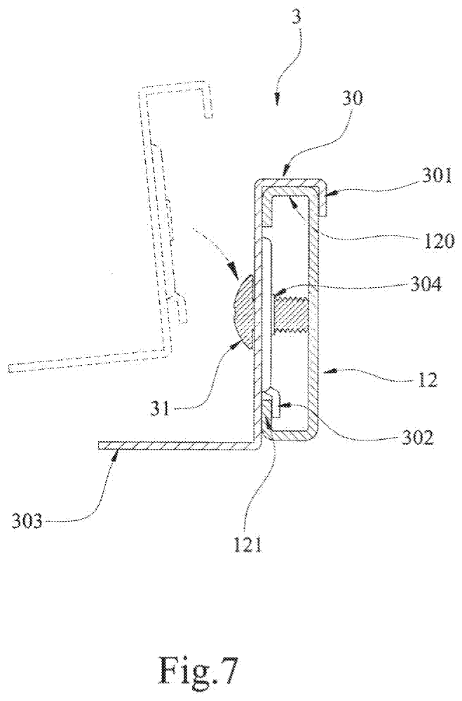

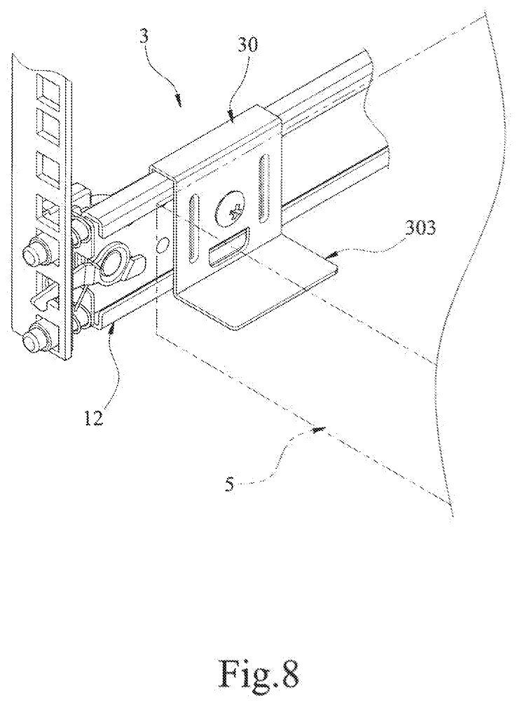

As shown in FIGS. 7 and 8, the support device 3 is connected to one side of the second rail 12 and includes a support member 30. The support member 30 includes a first snapping portion 301, a second snapping portion 302, a support portion 303 and a bore 304. A bolt 31 extends through the bore 304 of the support member 30 and contacts against the second rail 12. The support member 30 is installed to the second rail 12 by an angle, and the first snapping portion 301 is a recess and located corresponding to the engaging end 120 of the second rail 12. The second snapping portion 302 is located corresponding to the ridge 121 of the second rail 12. The support portion 303 is located corresponding to the shelf 5. The bore 304 is located corresponding to the bolt 31. The first and second snapping portions 301, 302 are snapped to the second rail 12 and is secured by the bolt 31 so that the support portion 303 of the support member 30 is able to support a shelf 5. When the server is retracted, the support portion 303 provide the server and prevents the cabinet from falling.

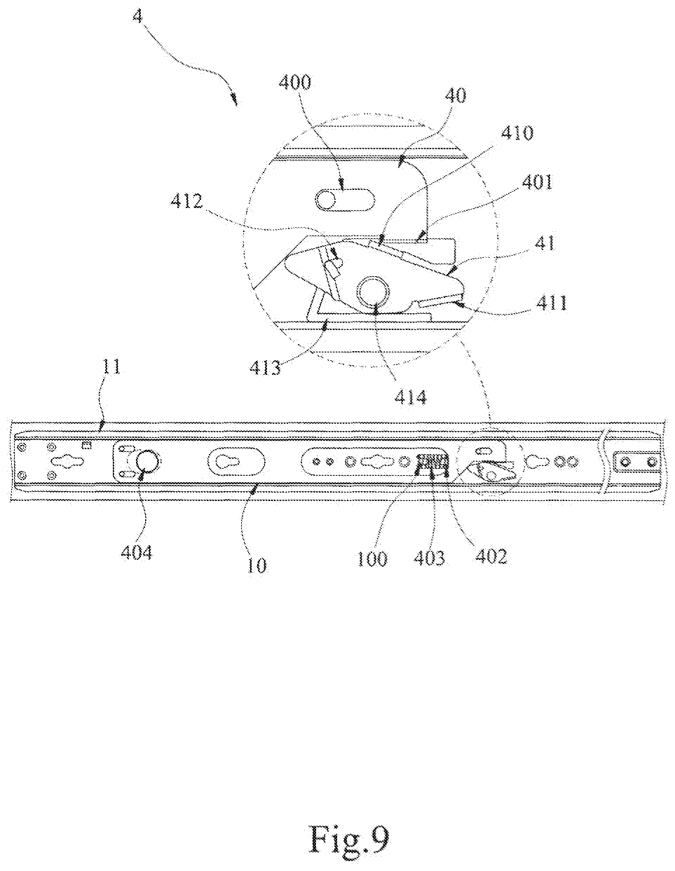

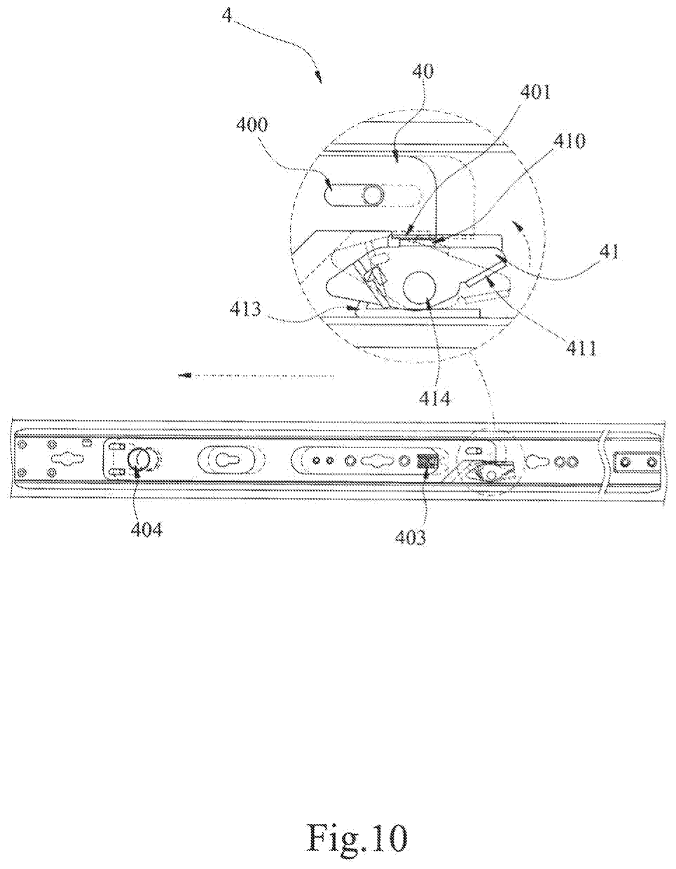

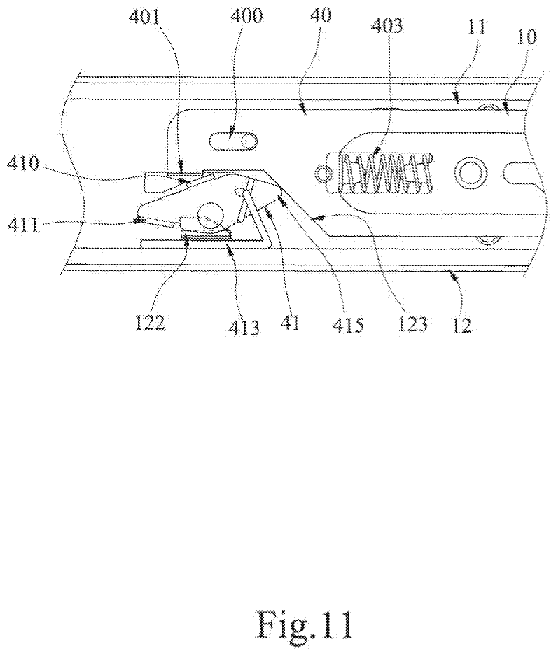

As shown in FIGS. 1, 2, 9, 10, 11 and 12, the locking device 4 is securely connected to the panel 10 and includes a release member 40 and a locking member 41. The locking member 41 is maintained in an inclined status by the torsion spring 413 so that the first engaging part 410 is located corresponding to the extension 401 of the release member 40. The second engaging part 411 is located corresponding to the stop 122 of the second rail 12.

When unlocking the locked status between the first and second rails 11, 12, the users pull the release member 40 toward one direction, and the extension 401 pushes the first engaging part 410 so that the locking member 41 is pivoted about the pivot member 414, such that the extension 401 becomes to be parallel to the first engaging part 410. Therefore, the second engaging part 411 is able to move over the stop 122 to unlock the locked status. Therefore, the first rail 11 can be separated from the second rail 12. That is to say, the locking device 4 is a protection mechanism to avoid the first rail 11 from being separated from the second rail 12. When installing the first rail 11 to the second rail 12, the inclined ramp 123 of the release member 40 is located corresponding to the rounded end 415 of the locking member 41, and the locking member 41 is pivoted to let the stop 122 move over the second engaging part 411 to install the first rail 11 to the second rail 12.

While we have shown and described the embodiment in accordance with the present invention, it should be clear to those skilled in the art that further embodiments may be made without departing from the scope of the present invention.

1. A rail assembly comprising:
a panel having a second engaging portion formed thereto, the panel connected to a locking device and one side of a first rail, the locking device located between the panel and the first rail, the locking device including a first contact portion which is located corresponding to the second engaging portion by a resilient member;
a second rail mounted to the first rail and including an installation device and a support device connected thereto, the installation device connected to an end of the second rail and including a connection member which includes a first part and a second part, the support device connected to one side of the second rail and including a support member, the support member including a first snapping portion, a second snapping portion, a support portion and a bore,
the first snapping portion being a recess and located corresponding to an engaging end formed on a top of the second rail, the support member being installed to the second rail by an angle to engage the engaging end of the second rail with the first snapping portion of the support member, the second snapping portion being located corresponding to a ridge of the second rail, and
the locking device including a release member and a locking member, the release member including multiple elongate holes, an extension, the first contact portion and the resilient member, the locking member including a first engaging part, a second engaging part, a slot, a torsion spring and a pivot member.

2. The rail assembly as claimed in claim 1, wherein the first part includes a first hole, the second part includes a second hole, the first and second holes each are an oval hole and are respectively and transversely defined in the first and second parts, a pin movably extends through the oval holes.

3. The rail assembly as claimed in claim 1, wherein a bolt extends through the bore of the support member and contacts against the second rail, the support portion is located corresponding to a shelf.

4. The rail assembly as claimed in claim 1, wherein the second rail includes a stop which is located corresponding to the locking member of the locking device.

5. The rail assembly as claimed in claim 1, wherein the release member of the locking device is movable in one direction to contact and pivot the locking member, and the first rail is pushed to separate from the second rail.

6. A rail assembly comprising:
a panel having a second engaging portion formed thereto, the panel connected to a locking device and one side of a first rail, the locking device located between the panel and the first rail, the locking device including a first contact portion which is located corresponding to the second engaging portion by a resilient member, and
a second rail mounted to the first rail and including an installation device and a support device connected thereto, the installation device connected to an end of the second rail and including a connection member which includes a first part and a second part, the first part including a first hole, the second part including a second hole, the first and second holes each being an oval hole, and respectively and transversely defined in the first and second parts, a pin movably extending through the oval holes wherein the pin is movable in adjustment direction perpendicular to the axial direction of the second rail.

7. A rail assembly comprising:
a panel having a second engaging portion formed thereto, the panel connected to a locking device and one side of a first rail, the locking device located between the panel and the first rail, the locking device including a first contact portion which is located corresponding to the second engaging portion by a resilient member;
a second rail mounted to the first rail and including an installation device and a support device connected thereto, the support device having a support portion that perpendicularly extends beyond the second rail, the support portion adapted to support shelves, and
the locking device including a release member and a locking member, the release member including multiple elongate holes, an extension, the first contact portion and the resilient member, the locking member including a first engaging part, a second engaging part, a slot, a torsion spring and a pivot member, the pivot member extending through the locking member and connected to the panel, the first engaging part extending perpendicularly from a top of the locking member, one end of the torsion spring engaged with the slot so as to maintain the first engaging part of the locking member to contact the extension of the release member, the release member of the locking device being movable in one direction to contact and pivot the locking member, and the first rail being pushed to separate from the second rail.
